(19) United States
(12) Patent Application Publication
(10) Pub. No.: US 2026/0099136 A1
(43) Pub. Date: Apr. 9, 2026

(54) SEMICONDUCTOR MANUFACTURING DEVICE, SEMICONDUCTOR MANUFACTURING PLANT, AND SEMICONDUCTOR MANUFACTURING METHOD

(71) Applicant: SUMCO CORPORATION, Tokyo (JP)

(72) Inventors: Yu MINAMIDE, Tokyo (JP); Naoyuki WADA, Tokyo (JP)

(73) Assignee: SUMCO CORPORATION, Tokyo (JP)

(21) Appl. No.: 19/141,408

(22) PCT Filed: Oct. 11, 2023
(86) PCT No.: PCT/JP2023/036906

§ 371 Date: Jun. 20, 2025

(30) Foreign Application Priority Data
Dec. 23, 2022 (JP) 2022-206528

(51) Int. Cl. G05B 19/418; H10P 72/00

(52) U.S. Cl. CPC G05B 19/41815; G05B 19/41865; H10P 72/0454; G05B 2219/45031

(57) ABSTRACT

A semiconductor manufacturing including plurality of processors and a number of loader-unloaders exceeding thereof. Each object to be treated is transported to a processor in a single unit and treated, and then is transported to the loader-unloader. The manufacturing lot of the object to be treated by each processor is carried into each loader-unloader while the remaining loader-unloader is left empty, thereafter each of the processors starts treatment, and while the object to be treated is being treated by each processor, based on manufacturing information of the object to be treated for each processor, the processor that finishes treatment relatively early is predicted, and before finishing the treatment by each processor, the manufacturing lot to be treated by the processor that has been predicted to finish treatment relatively early is carried into the loader-unloader that is currently empty.

### FIELD OF THE INVENTION

The present invention relates to a semiconductor manufacturing device, a semiconductor manufacturing plant, and a semiconductor manufacturing method.

### BACKGROUND OF THE INVENTION

For a semiconductor manufacturing device that is provided with a plurality of processing chambers and can set multiple transporting control patterns to the processing chamber, a control system of the semiconductor manufacturing device is known that collects data related to current running state and the current inventory lot, collects data related to wafer processing time tailored to a recipe indicating processing content for each lot scheduled to be treated by the semiconductor manufacturing device and a loss of time occurred during the treatment of each lot unit, calculates respectively the average lead time of all inventory lots for each wafer transporting control content based on each of the collected data, and selects the wafer transporting control content based on the size relation of each calculated average lead time (see Patent Literature 1). Accordingly, even when the loss of time exists during lot treatment, there is a possibility to instruct the semiconductor manufacturing device to appropriately perform the wafer transporting control treatment.

### RELATED ART

### Patent Literature

Patent Literature 1: Japanese Patent Laid-open Publication No. 2010-251507

### SUMMARY OF THE INVENTION

### Problems to Be Solved by the Invention

However, when the processing chamber for treating is determined for each manufacturing lot in the semiconductor manufacturing plant according to customer specifications and the like, the above described conventional technology cannot be applied.

The present invention undertakes to solve the issue of providing a semiconductor manufacturing device, a semiconductor manufacturing plant, and a semiconductor manufacturing method that can reduce manufacturing time even when the number of processors for treating is determined for each manufacturing lot wherein the semiconductor manufacturing device is provided with a plurality of processors and a number of loader-unloaders exceeding thereof.

### Means for Solving the Problems

The present invention provides a semiconductor manufacturing device, provided with a plurality of processors and a number of loader-unloaders exceeding thereof, where the processor for treating carries an object to be treated, which is determined for each manufacturing lot, into the loader-unloader in a unit of the manufacturing lot, each object to be treated is transported to the processor in a single unit and treated, and then is transported to the loader-unloader. The above concerns are solved by the semiconductor manufacturing device that carries the manufacturing lot of the object to be treated by each processor into each loader-unloader while the remaining loader-unloader is left empty, thereafter each of the processors starts treatment; and while the object to be treated is being treated by each processor, the processor that finishes treatment relatively early is predicted based on the manufacturing information of the object to be treated for each processor; and before finishing the treatment by each processor, the manufacturing lot to be treated by the processor that has been predicted to finish treatment relatively early is carried into the loader-unloader that is currently empty.

In addition, the present invention provides a semiconductor manufacturing method that uses a semiconductor manufacturing device provided with a plurality of processors and a number of loader-unloaders exceeding thereof carries, by the processor for treating, an object to be treated which is determined for each manufacturing lot into the loader-unloader in a unit of the manufacturing lot, thereafter transports, to the processor, and treats each object to be treated in a single unit, and then transports each object to be treated to the loader-unloader. The above concerns are solved by the semiconductor manufacturing method that starts the treatment by each processor after the manufacturing lot of the object to be treated by each processor is carried into each loader-unloader while the remaining loader-unloader is left empty; predicts the processor that finishes treatment relatively early while the object to be treated is being treated by each processor, based on the manufacturing information of the object to be treated for each processor; and carries, before finishing treatment by each processor, the manufacturing lot to be treated by the processor that has been predicted to finish treatment relatively early into the loader-unloader that is currently empty.

In the present invention, more preferably, when the processor starts treatment for a last or a second from the last object to be treated of the manufacturing lot that is present in the loader-unloader, the processor that finishes treatment relatively early is predicted.

Further, in the present invention, the manufacturing information of the object to be treated can include a processing time for the object to be treated and the number of objects to be treated to be included in a processing order or the manufacturing lot.

Further, in the present invention, more preferably, when the treatment of one manufacturing lot is finished in one processor, the treatment of another manufacturing lot is started by the one processor when another manufacturing lot to be treated by the one processor is present in any of the loader-unloaders.

The present invention also resolves the above concerns by a semiconductor manufacturing plant where a plurality of semiconductor manufacturing devices according to the present invention are installed.

The present invention preferably includes an integrated controller that aggregates the manufacturing information of the processor sent from the plurality of semiconductor manufacturing devices and predicts the processor that finishes treatment relatively early; a production management device that instructs the plurality of semiconductor manufacturing devices, based on the prediction of the integrated controller, to carry the manufacturing lot to be treated by the processor that has been predicted to finish treatment relatively early into the loader-unloader that is currently empty before finishing treatment by each processor; and a transport device that carries the manufacturing lot into the plurality of semiconductor manufacturing devices based on the instruction from the production management device.

### Effect of the Invention

According to the present invention, before finishing the treatment by each processor, for the semiconductor manufacturing device provided with a plurality of processors and a number of loader-unloaders exceeding thereof, the manufacturing lot to be treated by the processor that is predicted to finish treatment relatively early is carried into the loader-unloader that is currently empty. This allows the processor to continuously manufacture without an interval and reduce time waiting for the loader-unloader to start manufacturing. As a result, even when the processor for treating is determined for each manufacturing lot, the manufacturing time for the object to be treated can be reduced. In particular, when more than one semiconductor manufacturing devices provided with a plurality of processors are installed within the semiconductor manufacturing plant, by using a large number of processors equivalent to a plurality of devices, a wide variety of semiconductor products with different specifications for example can be manufactured efficiently resulting in increased effect.

### BRIEF DESCRIPTION OF THE DRAWINGS

FIG. 1 is a plane block diagram illustrating a vapor phase growth device according to an embodiment of a semiconductor manufacturing device of the present invention.

FIG. 2 is a schematic block diagram of the vapor phase growth device of FIG. 1, illustrating handling of a manufacturing lot and an object to be treated.

FIG. 3 is a time chart showing an example and a comparative example of handling of the manufacturing lot and the object to be treated using the vapor phase growth device in FIG. 2.

FIG. 4A is a time chart (part 1) illustrating a procedure of the example in FIG. 3.

FIG. 4B is a time chart (part 2) illustrating the procedure of the example in FIG. 3.

FIG. 4C is a time chart (part 3) illustrating the procedure of the example in FIG. 3.

FIG. 4D is a time chart (part 4) illustrating the procedure of the example in FIG. 3.

FIG. 5 is a flow chart illustrating steps of handling the manufacturing lot and the object to be treated by the vapor phase growth device in FIG. 2.

FIG. 6 is a block diagram illustrating an embodiment of a semiconductor manufacturing plant where a plurality of semiconductor manufacturing devices of FIG. 1 are installed.

### MODE FOR CARRYING OUT THE INVENTION

Hereafter, an embodiment of the present invention is described based on the drawings. The semiconductor manufacturing device and the semiconductor manufacturing method of the present invention imply a device and a method for manufacturing a semiconductor device, and are not limited in particular, but include a chemical vapor deposition device and method (CVD device) depositing a thin film on a surface of semiconductor, an etching device and method forming minute unevenness on the semiconductor, a cleaning device and method cleaning the surface of semiconductor, and the like. In the embodiment noted below, a vapor phase growth device and a method forming a silicon epitaxial film on a surface of a silicon single crystal wafer are cited as an example of the semiconductor manufacturing device and method, and the embodiment of the present invention is described.

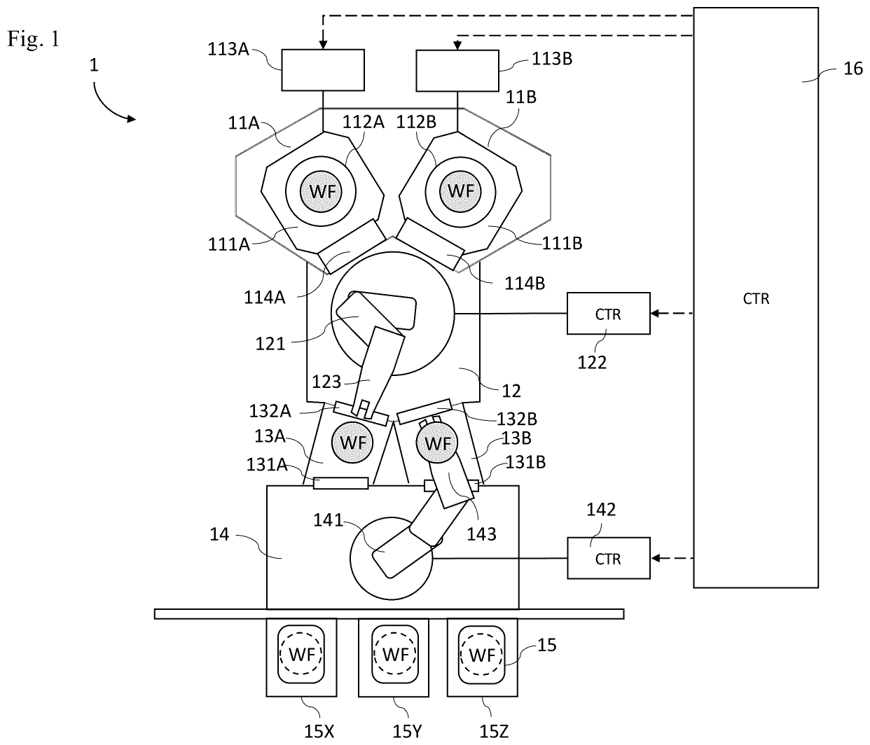

FIG. 1 is a plane block diagram illustrating a vapor phase growth device 1 according to the embodiment of the present invention. A main body of the vapor phase growth device 1 shown in the center of the diagram is illustrated in a plan view. The vapor phase growth device 1 of the present embodiment is what is known as a CVD device and is provided with a pair of reaction furnaces 11A and 11B; a wafer transfer chamber 12 which houses a first robot 121 that handles a wafer WF, such as a silicon single crystal wafer; a pair of load-lock chambers 13A and 13B; a factory interface 14 which houses a second robot 141 that handles the wafer WF; and load ports 15X, 15Y, and 15Z which house a wafer storage container 15 (also called a cassette case or FOUP) storing a plurality of the wafers WF.

The factory interface 14 is a zone configured to have the same air atmosphere as a room (clean room) of load ports 15X, 15Y, and 15Z in which the wafer storage container 15 is carried in and carried out. The factory interface 14 is provided with the second robot 141, which extracts a before-treatment wafer WF that is stored in the wafer storage container 15 and deposits the wafer WF in the load-lock chamber 13, and also stores an after-treatment wafer WF transported to the load-lock chamber 13 in the wafer storage container 15. The second robot 141 is controlled by a second robot controller 142, and a second blade 143 mounted on a distal end of a robot hand displaces along a predetermined trajectory that has been taught in advance.

First doors 131A and 131B capable of opening and closing with an airtight seal are provided between each of the load-lock chambers 13A and 13B with the factory interface 14, while second doors 132A and 132B similarly capable of opening and closing with an airtight seal are provided between each of the load-lock chambers 13A and 13B with the wafer transfer chamber 12. In addition, each of the load-lock chambers 13A and 13B serves as a space where atmospheric gas exchange takes place between the wafer transfer chamber 12, which is configured to have an inert gas atmosphere, and the factory interface 14, which is configured to have an air atmosphere. Therefore, an exhaust device that vacuum-evacuates an interior of the load-lock chambers 13A and 13B and a supply device that supplies inert gas to the load-lock chambers 13A and 13B are provided.

For example, when the before-treatment wafer WF is transported from the wafer storage container 15 to the wafer transfer chamber 12 via the load-lock chamber 13A, in a state where the first door 131A on the factory interface 14 side is closed, the second door 132A on the wafer transfer chamber 12 side is closed, and the load-lock chamber 13A has an inert gas atmosphere, the wafer WF is extracted from the wafer storage container 15 using the second robot 141, the first door 131A on the factory interface 14 side is opened, and the wafer WF is transported to the load-lock chamber 13A. Next, after the first door 131A on the factory interface 14 side is closed and the load-lock chamber 13A is restored to an inert gas atmosphere, the second door 132A on the wafer transfer chamber 12 side is opened and the wafer WF is transported to the wafer transfer chamber 12 using the first robot 121.

Conversely, when the after-treatment wafer WF is transported from the wafer transfer chamber 12 to the wafer storage container 15 via the load-lock chamber 13A, in a state where the first door 131A on the factory interface 14 side is closed, the second door 132A on the wafer transfer chamber 12 side is closed, and the load-lock chamber 13A has an inert gas atmosphere, the second door 132A on the wafer transfer chamber 12 side is opened and the wafer WF in the wafer transfer chamber 12 is transported to the load-lock chamber 13A using the first robot 121. Next, after the second door 132A on the wafer transfer chamber 12 side is closed and the load-lock chamber 13A is restored to an inert gas atmosphere, the first door 131A on the factory interface 14 side is opened and the wafer WF is transported to the wafer storage container 15 using the second robot 141.

The wafer transfer chamber 12 is configured by a sealed chamber, connected on one side to the load-lock chambers 13A and 13B via the second doors 132A and 132B that are capable of opening and closing and have an airtight seal, and connected on the other side via gate valves 114A and 114B that are capable of opening and closing and have an airtight seal. The first robot 121, which transports the before-treatment wafer WF from the load-lock chambers 13A and 13B to the reaction chambers 111A and 111B and transports the after-treatment wafer WF from the reaction chambers 111A and 111B to the load-lock chambers 13A and 13B, is installed on the wafer transfer chamber 12. The first robot 121 is controlled by a first robot controller 122, and a first blade 123 mounted on a distal end of a robot hand displaces along an operation trajectory that has been taught in advance.

A 16 that integrates entire control of the vapor phase growth device 1, the first robot controller 122, and the second robot controller 142 mutually send and receive control signals. In addition, when an operation command signal from the integrated controller 16 is sent to the first robot controller 122, the first robot controller 122 controls the operation of the first robot 121, and an operation result of the first robot 121 is sent from the first robot controller 122 to the integrated controller 16. Accordingly, the integrated controller 16 recognizes an operation status of the first robot 121. Similarly, when an operation command signal from the integrated controller 16 is sent to the second robot controller 142, the second robot controller 142 controls the operation of the second robot 141, and an operation result of the second robot 141 is sent from the second robot controller 142 to the integrated controller 16. Accordingly, the integrated controller 16 recognizes an operation status of the second robot 141.

Inert gas is supplied to the wafer transfer chamber 12 from an inert gas supply device not shown in the drawings, and gas in the wafer transfer chamber 12 is cleaned with a scrubber (scrubbing dust collector) that is connected to an exhaust port, after which the gas is released outside the system. Although a detailed depiction is omitted, this type of scrubber can use a conventionally known pressurized water scrubber, for example.

The reaction furnaces 11A and 11B are devices for growing an epitaxial film on a surface of the wafer WF using the CVD method, and include reaction chambers 111A and 111B; susceptors 112A and 112B on which the wafer WF is placed and rotated are provided inside the reaction chambers 111A and 111B. In addition, gas supply devices 113A and 113B are provided that supply hydrogen gas and raw material gas for growing a CVD film (when the CVD film is a silicon epitaxial film, the raw material gas may be silicon tetrachloride SiCl₄ or trichlorosilane SiHCl₃, for example) to the reaction chambers 111A and 111B. Although omitted from the drawings, a heat lamp for raising the temperature of the wafer WF to a predetermined temperature is provided on the periphery of the reaction chambers 111A and 111B. Further, gate valves 114A and 114B are provided between the reaction chambers 111A and 111B and the wafer transfer chamber 12, and airtightness with the wafer transfer chamber 12 of the reaction chambers 111A and 111B is ensured by closing the gate valves 114A and 114B. Various controls, such as driving the susceptors 112A and 112B of these reaction furnaces 11A and 11B, supply and stoppage of gas by the gas supply devices 113A and 113B, turning the heat lamp on and off, and opening and closing the gate valves 114A and 114B, are controlled by a command signal from the integrated controller 16. The vapor phase growth device 1 shown in FIG. 1 depicts an example provided with a pair of reaction furnaces 11A and 11B, but may have three or more reaction furnaces.

A scrubber (scrubbing dust collector) having a similar configuration to that of the wafer transfer chamber 12 is also provided to the reaction furnaces 11A and 11B. In other words, hydrogen gas or raw material gas supplied from the gas supply devices 113A and 113B is cleaned by the scrubber connected to an exhaust port provided to the reaction chambers 111A and 111B and then is released outside the system. For example, a conventionally known pressurized water scrubber can be used for this scrubber, as well.

When the silicon epitaxial film is formed on the silicon single crystal wafer using the vapor phase growth device 1 provided with two reaction furnaces 11A and 11B as shown in FIG. 1, depending on the product specifications of the wafer WF, it may be determined at the time of planning for production which reaction furnace 11A or 11B will be used. For example, when the susceptors 112A and 112B provided to the reaction furnaces 11A and 11B are different according to the product specifications, based on the susceptor being used, the reaction furnace 11A or 11B to manufacture the wafer WF is determined. In addition, manufacturing the wafer WF having the same manufacturing lot in the same reaction furnace 11A or 11B keeps the quality uniform between the manufacture lots and is also better for performing defect analysis survey.

Therefore, all wafers WF stored in a single wafer storage container 15 are transported and treated one by one to one of the predetermined reaction furnaces 11A and 11B, and then are returned to the original wafer storage container 15. In other words, when the wafer storage container 15 storing the wafers WF to be treated in the reaction furnace 11A is carried into the load port 15X in FIG. 1, all wafers WF are transported to the reaction furnace 11A and treated, then are returned to the wafer storage container 15 of the load port 15X. On the other hand, when the wafer storage container 15 storing the wafers WF to be treated in the reaction furnace 11B is carried into the load port 15Y in FIG. 1, all wafers WF are transported to the reaction furnace 11B and treated, and then are returned to the wafer storage container 15 of the load port 15Y.

In this way, transporting control of the wafer, in which the wafer WF of the manufacturing lot carried into one load port 15X is only treated in one reaction furnace 11A, and the wafer WF of another manufacturing lot carried into another load port 15Y is only treated in another reaction furnace 11B, is also called a parallel operation mode. In contrast, transporting control of the wafer, in which the wafer WF of the manufacturing lot carried into one load port 15X is sequentially treated in one of empty reaction furnaces 11A and 11B, and after all the wafers WF of the manufacturing lot carried into the load port 15X are treated, the wafer of the manufacturing lot carried into another load port 15Y is sequentially treated in one of empty reaction furnaces 11A or 11B, is also called a serial operation mode.

In this example, when manufactured by transporting control in the parallel operation mode, as shown in FIG. 1, when the vapor phase growth device 1 includes the number of load ports 15A, 15B, and 15C exceeding the number of reaction furnaces 11A and 11B, that is when the number of reaction furnaces is N, the vapor phase growth device 1 includes (N+1) or more load ports, the inventors of the present invention have investigated thoroughly whether the wafer storage container 15 of the manufacturing lot to be treated in one of N reaction furnaces should be carried into (N+1) or more load ports. In this example, as shown in FIG. 1, a case with two reaction furnaces 11A and 11B and three load ports 15A, 15B, and 15C is considered.

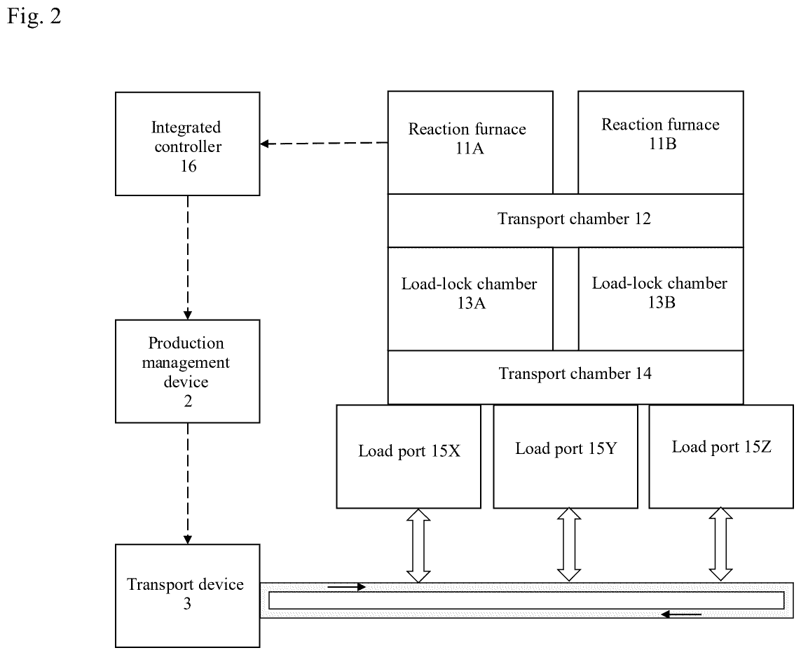

FIG. 2 is a schematic block diagram of the vapor phase growth device 1 of FIG. 1, illustrating handling of the wafer WF (object to be treated) of the same manufacturing lot. A production management device 2 shown in FIG. 2 is a device that integrally manages all manufacturing devices of a production process, including a plurality of vapor phase growth devices 1. The production management device 2 prepares a production plan for a product, and also manages the production plan by outputting the prepared production plan of the product to each manufacturing device including a plurality of vapor phase growth devices 1 and a transport device 3, and by inputting progress information from each manufacturing device. The transport device 3 is a system transporting the wafer WF that have finished treatment in the previous step to the next step in a state being stored in the wafer storage container 15, and based on a command from the production management device 2, the wafer storage container 15 of the predetermined manufacturing lot in the previous step is carried into one of the load ports 15X, 15Y, and 15Z of the vapor phase growth device 1 of the present embodiment.

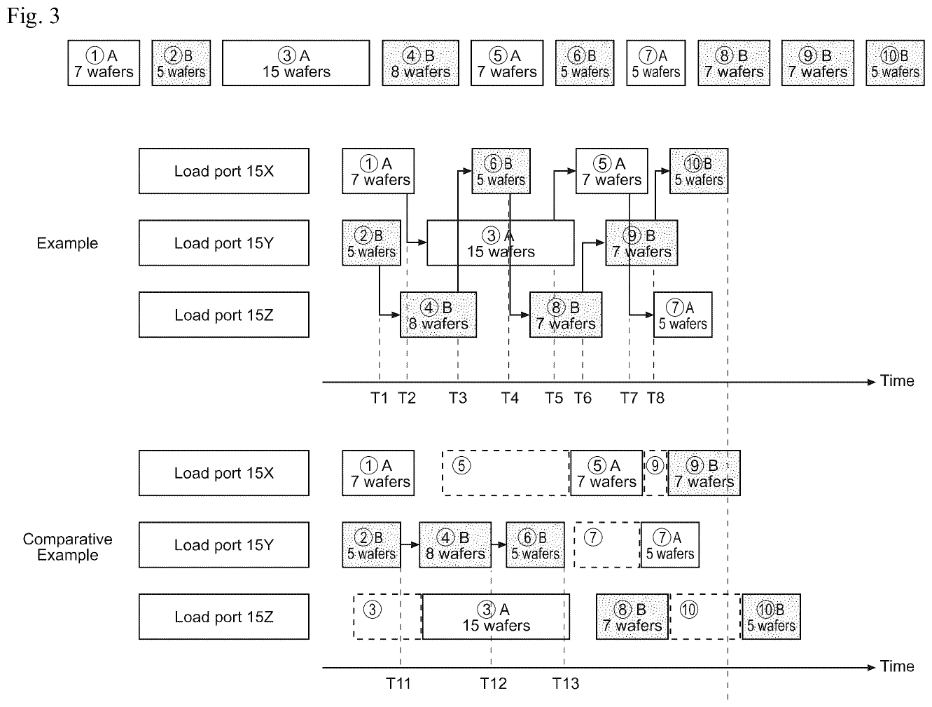

FIG. 3 is a time chart showing an example and a comparative example when handling the wafer WF of the same manufacturing lot using the vapor phase growth device 1 in FIG. 2. The upper drawing of FIG. 3 shows an example of the production plan prepared by the production management device 2, where “circled number” indicates the order of production plan, “A or B” determines the reaction furnaces 11A or 11B for treating, and “quantity” shows the number of wafers WF included in a single manufacturing lot. For example, a first manufacturing lot includes seven wafers WF to be treated in the reaction furnace 11A, and a second manufacturing lot includes five wafers WF to be treated in the reaction furnace 11B. In this example, the production plan is, for every ten manufacturing lots from the first to tenth, 34 wafers WF are treated in the reaction furnace 11A, and 37 wafers WF are treated in the reaction furnace 11B. Also, the production plan prepared by the production management device 2 is determined as desired in accordance with the product specifications to be manufactured, and there are no particular rules.

First, the inventors of the present invention have investigated how productivity will turn out when the wafer storage container 15 is carried into three load ports 15X, 15Y, and 15Z in sequence according to the order (circled number) of the production plan indicated in the upper drawing of FIG. 3. As shown in the lower drawing of FIG. 3, the first manufacturing lot is carried into the load port 15X, the second manufacturing lot is carried into the load port 15Y, and the third manufacturing lot is carried into the load port 15Z. The wafer WF of the first manufacturing lot carried into the load port 15X should be treated in the reaction furnace 11A, and thus the treatment is started in the reaction furnace 11A and at the same time, the wafer WF of the manufacturing lot carried into the load port 15Y should be treated in the reaction furnace 11B, and thus the treatment is started in the reaction furnace 11B. However, the two reaction furnaces 11A and 11B are performing treatment at this point, and therefore, the wafer WF of the manufacturing lot carried into the remaining load port 15Z is on a standby state. This standby state is shown by the dotted frame in the lower drawing of FIG. 3.

In the lower drawing of FIG. 3, at time T11, the treatment in reaction furnace 11B is finished and the wafer storage container 15 in which the after-treatment wafer WF is stored is carried out from the load port 15Y. This leaves the reaction furnace 11B in an empty state. However, at this point in time, the manufacturing lot of load port 15Z waiting to be treated is a manufacturing lot that should be treated in reaction furnace 11A, not the reaction 11B. Therefore, the reaction furnace 11B in the empty state has no choice but to carry the wafer storage container 15 in which the fourth manufacturing lot is stored into the load port 15Y. And after the wafer storage container 15 in which the fourth manufacturing lot is stored is carried into the load port 15Y, the wafer WF of this manufacturing lot is transported to the reaction furnace 11B and treated. At this timing of time T11, the wafer WF of the manufacturing lot of the load port 15Z on the standby state needs to keep the standby state, resulting in a loss of time. Further, the reaction furnace 11B cannot start treatment until the next wafer storage container 15 is carried into the load port 15Y in empty state, and therefore this also results in the loss of time. The loss of time like this occurs in the fifth manufacturing lot at time T12 also and in the seventh manufacturing lot at T13 as well, as shown in the lower drawing of FIG. 3.

In other words, when the wafer storage container 15 is carried into the three load ports 15X, 15Y, and 15Z in sequence simply following the order (circled number) of production plan, depending on the end timing of the treatment in the two reaction furnaces 11A and 11B, the loss of time may occur at times T11 (third manufacturing lot), T12 (fifth manufacturing lot), and T13 (seventh manufacturing lot) which causes a decrease in productivity.

In contrast, the vapor deposition device 1 of the present embodiment carries the manufacturing lot of the wafer WF to be treated in each of the reaction furnaces 11A and 11B into each of the load ports 15X and 15Y, while the remaining load port 5Z is left empty without carrying in the wafer storage container 15, after which each of the reaction furnaces 11A and 11B starts the treatment. Next, while treating the wafer WF in each of the reaction furnaces 11A and 11B, based on the manufacturing information of the wafer WF in each of the reaction furnaces 11A and 11B, prediction is made which reaction furnace 11A or 11B finishes treatment relatively early. Then, before finishing the treatment in each of the reaction furnaces 1A and 11B, the wafer storage container 15 of the manufacturing lot to be treated in the reaction furnace 11A or 11B that is predicted to finish treatment relatively early is carried into the load port 15Z that is currently empty.

In this example, timing to predict which reaction furnace 11A or 11B finishes treatment relatively early is not particularly limited and can be any timing during the treatment of the wafer WF in each of the reaction furnaces 11A and 11B. However, more preferably, when starting the treatment in the reaction furnaces 11A and 11B for the last wafer WF or the second from the last wafer WF of the manufacturing lots that are present in the load ports 15X and 15Y, prediction is made which reaction furnace 11A or 11B finishes treatment relatively early. This is because the treatment is about to end, so the manufacturing error is smaller and the prediction is more accurate.

In addition, the manufacturing information of the wafer WF used for prediction includes the processing time for the wafer WF, the processing order of the wafer, or the number of wafers WF included in the manufacturing lot. For example, using the manufacturing information where the manufacturing lot has five wafers WF and the processing time for a single wafer WF is n hours, the last or the second from the last wafer WF can be identified and the time to finish the treatment of the last wafer WF can be calculated.

When the treatment of one manufacturing lot is finished in one of the reaction furnaces 11A or 11B, it is more preferable to start the treatment of another manufacturing lot without an interval in one of the reaction furnaces 11A or 11B when another manufacturing lot to be treated in one of the reaction furnaces 11A or 11B is present in any of the load ports. This allows the loss of time to be as close to zero as possible.

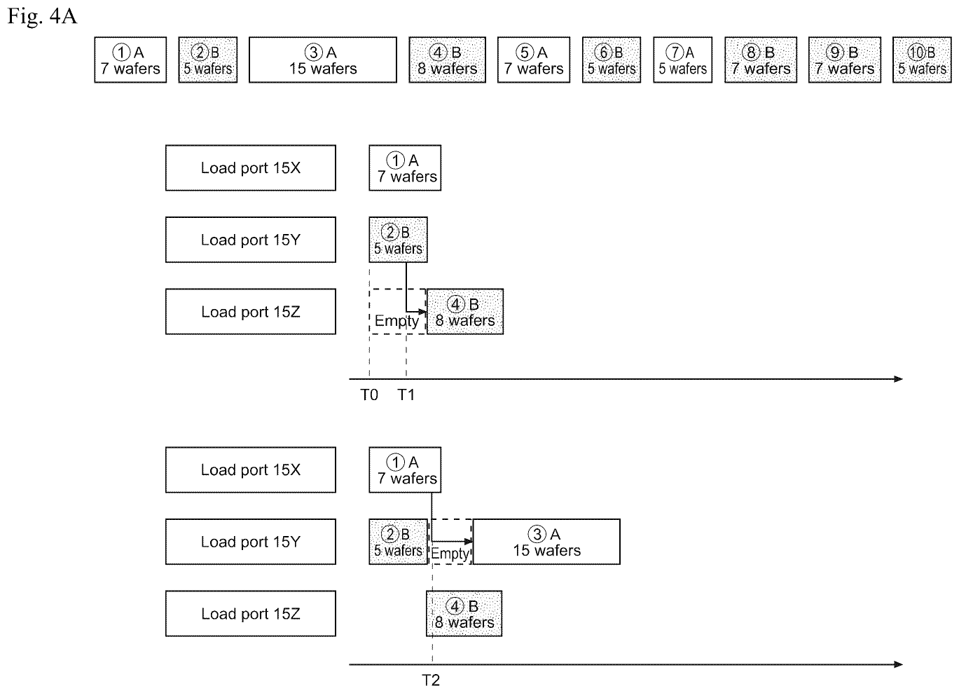

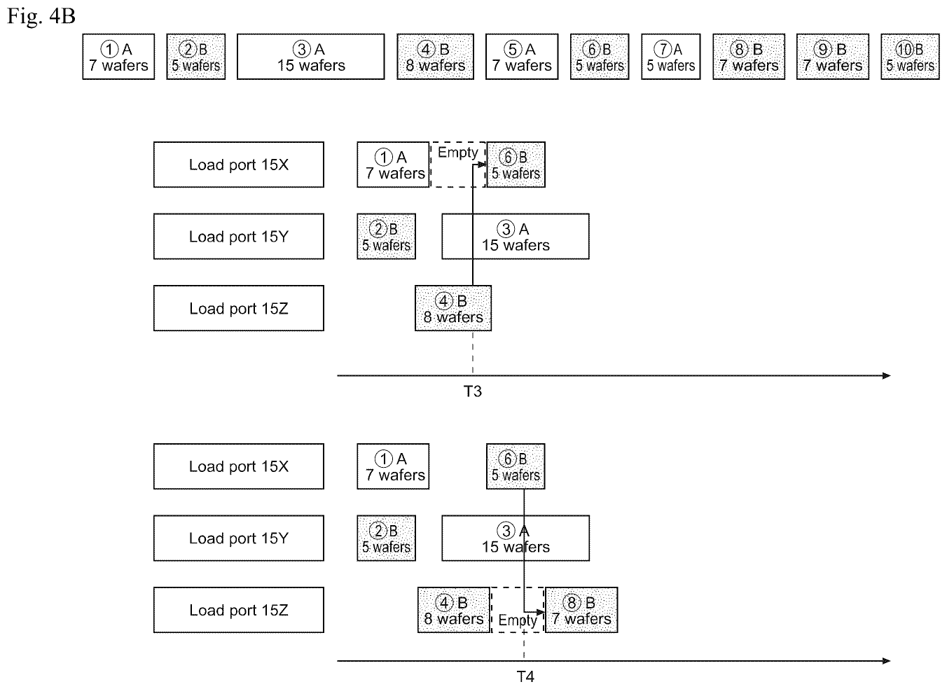

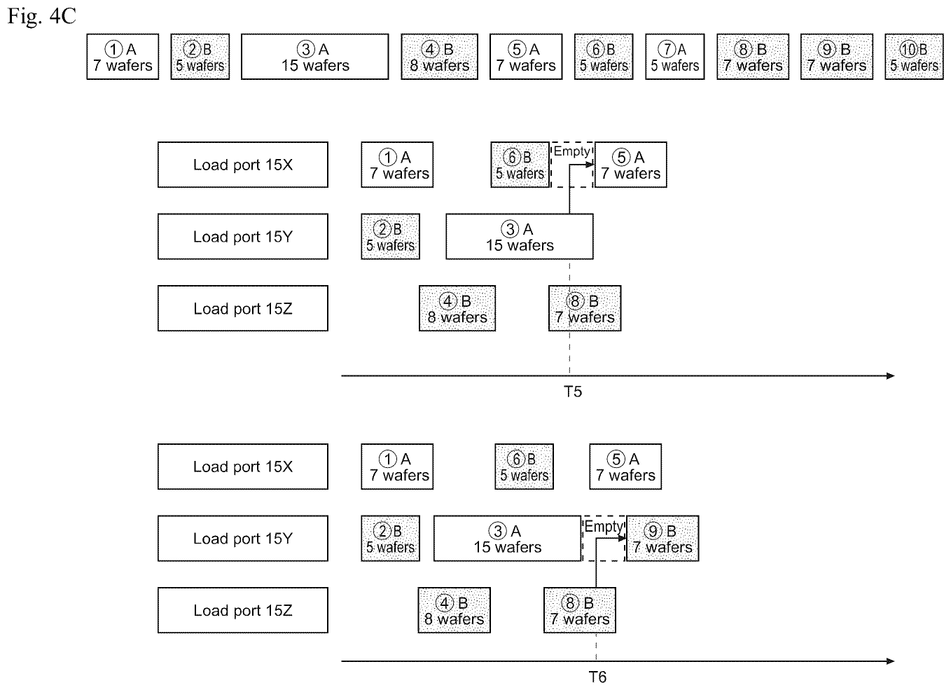

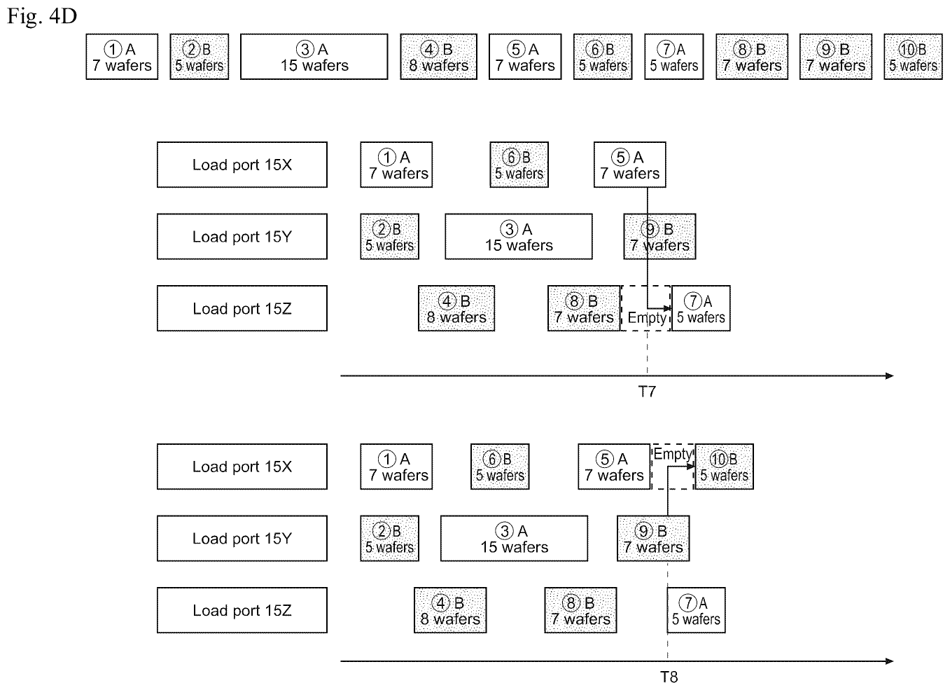

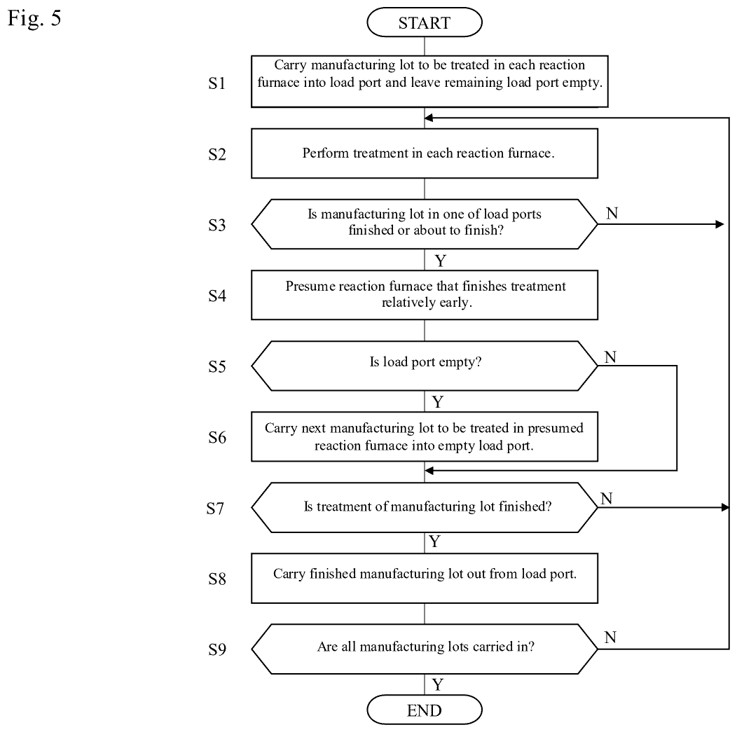

The central drawing of FIG. 3 is a time chart showing an example when handling the wafer WF of the same manufacturing lot using the vapor phase growth device 1 in FIG. 2, and FIGS. 4A to 4D are time charts illustrating procedures of the example in FIG. 3. In addition, FIG. 5 is a flow chart illustrating steps of handling the manufacturing lot and the wafer WF by the vapor phase growth device 1 of the present embodiment. With reference to the central drawing of FIG. 3 and FIGS. 4A to 4D, steps of handling the manufacturing lot and wafer WF of the present embodiment are described according to the flow chart in FIG. 5.

A specific example of the production plan of manufacturing lot is described below as illustrated in the upper drawing of FIG. 3, however when a command is issued from the integrated controller 16 of the vapor phase growth device 1 to the transport device 3 via the production management device 2, regardless of the order of production plan indicated by the circled number, the wafer storage container 15 of the desired manufacturing lot can be carried into the desired load ports 15X, 15Y, and 15Z.

First, at the beginning of operation of one day, there is no wafer WF in either reaction furnaces 11A or 11B, and no wafer storage container 15 is present in any of the load ports 15X, 15Y, and 15Z, and therefore, in step S1, the wafer storage container 15 of the manufacturing lot to be treated in each of the reaction furnaces 11A and 11B is carried into the load ports 15X and 15Y, and the remaining load port 15Z is left empty. This state is shown at time T0 in a central drawing of 4A. The first manufacturing lot is carried into the load port 15X, the second manufacturing lot is carried into the load port 15Y, and the load port 15Z is left empty.

In the next step S2, the wafers WF of the first manufacturing lot that are carried into the load port 15X is transported one by one to the reaction furnace 11A to start treatment, while the wafers WF of the second manufacturing lot that are carried into the load port 15Y is transported one by one to the reaction furnace 11B to start treatment.

In step S3, it is determined whether the manufacturing lot carried into each of the load port 15X and load port 15Y is finished or is about to finish (the second from the last wafer, for example). This determination can be made from the number of wafers WF (product information) included in the manufacturing lot output from the production management device 2 and the current number of treated wafers calculated by the integrated controller 16 of the vapor phase growth device 1. In step S3, when the manufacturing lot carried into each of the load port 15X and load port 15Y is finished or not about to finish, the process returns to step S2 and continues the treatment in reaction furnaces 11A and 11B.

In step S3, when one of the manufacturing lots carried into the load port 15X and load port 15Y is finished or is about to finish, the step moves to step S4 to presume which of the two reaction furnaces 11A and 11B currently in treatment finishes treatment early. This state is shown at time T1 in the central drawing of 4A. Since the second manufacturing lot carried into the load port 15Y is about to finish, at this time T1, based on the number of wafers WF (one wafer for the last wafer WF, two wafers for the second from the last) that have not finished the treatment in the reaction furnace 11B and the processing time in the reaction furnace 11B, time to finish the treatment in the reaction furnace 11B is calculated. At the same time, at time T1, based on the number of wafers WF that have not finished the treatment in the reaction furnace 11A and the processing time per wafer, time to finish the treatment in the reaction furnace 11A is calculated. These are compared to presume which of the two reaction furnaces 11A and 11B finishes the treatment early. In this example, the reaction furnace 11B finishes the treatment earlier.

In step S5, it is determined whether an empty space exists in the load ports 15X, 15Y, and 15Z, and the step moves to step S7 when there is no empty space, but moves to step S6 in this case since the load port 15Z is empty. In step S6, the wafer storage container 15 of the manufacturing lot to be treated in the reaction furnace 11B that is presumed to finish the treatment relatively early is selected from the manufacturing lot of production plan and carried into the load port 15Z. As shown in the central drawing of FIG. 4A, the fourth manufacturing lot is carried into the load port 15Z. Although the order in the production plan is on third, since the third manufacturing lot is a manufacturing lot to be treated in the reaction furnace 11A, this is not carried into the load port 15Z.

In the subsequent step S7, it is determined whether all wafers WF of the manufacturing lot carried into each load ports 15X, 15Y, and 15Z have finished the treatment, and the manufacturing lot where all the wafers WF have not finished the treatment returns to step S2 and continues the treatment. In step S7, the manufacturing lot where all the wafers WF have finished the treatment moves to step S8, and in step S8, the wafer storage container 15 of the finished manufacturing lot is carried out by the transport device 3 from the load port thereof. For example, as shown in the central drawing of FIG. 4A, when all the wafers WF of the second manufacturing lot that are carried into the load port 15Y have finished the treatment, the transport device carries this wafer storage container 15 out from the load port 15Y. This leaves the load port 15Y empty and at the same time, the reaction furnace 11B also moves to a state with no wafers WF.

In the subsequent step S9, it is determined whether all manufacturing lots in the production plan have finished being carried in, and this routine ends when finished, however when the manufacturing lots are not finished being carried in, the process returns to step S2 and continues the treatment in the reaction furnaces 11A and 11B. Here, as shown in the central drawing of FIG. 4A, the reaction furnace 11B is also in a state with no wafers WF and furthermore, the fourth manufacturing lot to be treated in the reaction furnace 11B is carried into the load port 15Z, and therefore, the wafers WF of this fourth manufacturing lot are transported one by one to the reaction furnace 11B and the treatment is started. This allows the reaction furnace 11B to continuously perform from the end of treatment for the second manufacturing lot to the start of the treatment for the fourth manufacturing lot, and the loss of time can be as close to zero as possible.

When the treatment for the fourth manufacturing lot is started in the reaction furnace 11B, in the subsequent step S3, once again, it is determined whether the manufacturing lot carried into each of the load port 15X and load port 15Y is finished or is about to finish (the second from the last wafer, for example). Then, in step S3, when one of the manufacturing lots carried into the load port 15X and load port 15Z is finished or is about to finish, the process moves to step S4 to presume which of the two reaction furnaces 11A and 11B currently in treatment finishes treatment early. This state is shown at time T2 in the lower drawing of FIG. 4A. Since the first manufacturing lot carried into the load port 15X is about to finish, at this time T2, based on the number of wafers WF that have not finished the treatment in the reaction furnace 11A and the processing time in the reaction furnace 11A, time to finish the treatment in the reaction furnace 11A is calculated. At the same time, at time T2, based on the number of wafers WF that have not finished the treatment in the reaction furnace 11B and the processing time per wafer, time to finish the treatment in the reaction furnace 11B is calculated. These are compared to presume which of the two reaction furnaces 11A and 11B finishes the treatment early. In this example, the reaction furnace 11A finishes the treatment earlier.

In step S5, it is determined whether the empty space exists in the load ports 15X, 15Y, and 15Z, and the step moves to step S6 in this case since the load port 15Y is empty. In step S6, the wafer storage container 15 of the manufacturing lot to be treated in the reaction furnace 11A that is presumed to have finished the treatment relatively early is selected from the manufacturing lot of production plan and carried into the load port 15Y. Since the third manufacturing lot is a manufacturing lot that should be treated in the reaction furnace 11A, the third manufacturing lot is carried into the load port 15Y as shown in the lower drawing of FIG. 4A.

In the subsequent step S7, it is determined whether all wafers WF of the manufacturing lot carried into each load ports 15X, 15Y, and 15Z have finished the treatment, and as shown in the lower drawing of FIG. 4A, after all wafers WF of the first manufacturing lot that is carried into the load port 15X have finished the treatment, the transport device carries this wafer storage container 15 out from the transport device 15X. This leaves the load port 15X empty and at the same time, reaction furnace 11A also moves to a state with no wafers WF. Since there are no wafers WF in reaction furnace 11A and furthermore, the third manufacturing lot to be treated in the reaction furnace 11A is carried into the load port 15Y, the wafers WF of this third manufacturing lot is transported one by one to the reaction furnace 11A and the treatment is started. This allows the reaction furnace 11A to continuously perform from the end of treatment for the first manufacturing lot until the start of the treatment for the third manufacturing lot, and the loss of time can be as close to zero as possible.

At each timing of times T3 to T8 illustrated in FIGS. 4B to 4D, similarly determination in step S4 is made to presume which of the two reaction furnaces 11A and 11B finishes treatment early. Then, the wafer storage container 15 of the manufacturing lot to be treated in the reaction furnaces 11A or 11B that is presumed to finish the treatment earlier is carried into the empty load ports 15X, 15Y, or 15Z. This allows the reaction furnaces 11A and 11B to continuously perform from the end of treatment for one manufacturing lot until the start of the treatment for another manufacturing lot, and the loss of time can be as close to zero as possible.

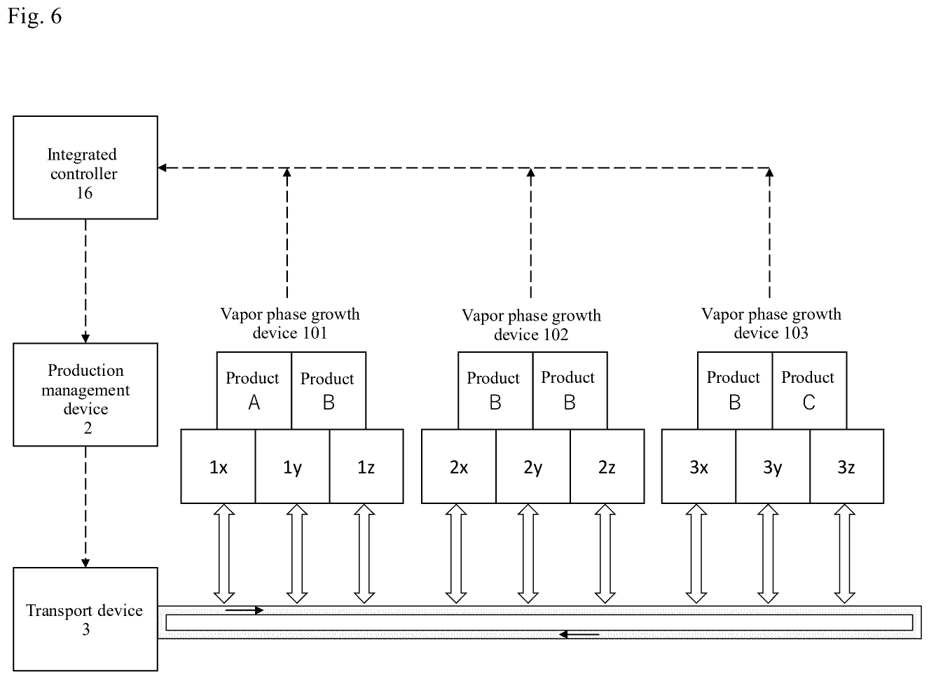

FIG. 6 is a block diagram illustrating an embodiment of a semiconductor manufacturing plant where a plurality of semiconductor manufacturing devices of FIG. 1 are installed, and specifically, the block diagram illustrates a semiconductor manufacturing plant with three vapor phase growth devices 101, 102, and 103. Each of the vapor phase growth devices 101, 102, and 103 has the same configuration as the vapor phase growth device 1 illustrated in FIGS. 1 and 2, and the vapor phase growth device 101 manufactures a product specification A in one reaction furnace and manufactures a product specification B in another reaction furnace; the vapor phase growth device 102 manufactures the product specification B in both reaction furnaces; and the vapor phase growth device 103 manufactures the product specification B in one reaction furnace and manufactures a product specification C in another reaction furnace.

The integrated controller 16 is a computer that integrates control of three vapor phase growth devices 101, 102, and 103 respectively, and controls operation of each of the vapor phase growth devices 101, 102, and 103. In addition, the manufacturing information for each reaction furnace sent from each of the three vapor phase growth devices 101, 102, and 103 is aggregated to integrally predict which reaction furnace finishes the treatment relatively early. For example, since the product specification B can be treated by the three vapor phase growth devices 101, 102, and 103, the manufacturing information of the reaction furnace in which the product specification B is in progress can be aggregated to predict which reaction furnace finishes the treatment relatively early, thereby reducing waiting time for the product.

The production management device 2 is a device that integrally manages all manufacturing devices of the production process of the semiconductor manufacturing plant including three vapor phase growth devices 101, 102, and 103, and instructs the three vapor phase growth devices 101, 102, and 103, based on the prediction from the integrated controller 16, to carry the manufacturing lot to be treated in the reaction furnace that is predicted to finish treatment relatively early into the loader-unloader that is currently empty before finishing the treatment in the reaction furnaces for the three vapor phase growth devices 101, 102, and 103 respectively.

The transport device 3 is a system transporting the wafer WF that have finished treatment in the previous step to the next step in a state stored in the wafer storage container 15, and based on the command from the production management device 2, the wafer storage container 15 of the predetermined manufacturing lot in the previous step is carried into one of the load ports 1x, 1y, 1z, 2x, 2y, 2z, 3x, 3y, and 3z of the three vapor phase growth devices 101, 102, and 103.

The vapor phase growth device 1 corresponds to the semiconductor manufacturing device of the present invention, the reaction furnaces 11A and 11B correspond to the processor of the present invention, the load ports 15X, 15Y, and 15Z correspond to the loader-unloader of the present invention, and the wafer WF corresponds to the object to be treated of the present invention.

### DESCRIPTION OF REFERENCE NUMERALS

1 . . . Vapor phase growth device
11A, 11B . . . Reaction furnace (Processor)
111A, 111B . . . Reaction chamber
112A, 112B . . . Susceptor
113A, 113B . . . Gas supply device
114A, 114B . . . Gate valve
12 . . . Wafer transfer chamber
121 . . . First robot
122 . . . First robot controller
123 . . . First blade
13A, 13B . . . Load-lock chamber
131A, 131B . . . First door
132A, 132B . . . Second door
14 . . . Factory interface
141 . . . Second robot
142 . . . Second robot controller
143 . . . Second blade
15 . . . Wafer storage container
15X, 15Y, 15Z . . . Load port (Loader-unloader)
16 . . . Integrated controller
2 . . . Production management device
3 . . . Transport device
WF . . . Wafer (Object to be treated)

1. A semiconductor manufacturing device comprising a plurality of processors and a number of loader-unloaders exceeding thereof, for an object to be treated that is transported according to a production plan determined as desired, where a processor for treating carries an object to be treated, which is determined for each manufacturing lot, into the loader-unloader in a unit of the manufacturing lot, each object to be treated is transported to the processor in a single unit and treated, and then is transported to the loader-unloader,
wherein the manufacturing lot of the object to be treated by each processor is carried into each loader-unloader while the remaining loader-unloader is left empty, thereafter each of the processors starts treatment;
while the object to be treated is being treated by each processor, the processor that finishes treatment relatively early is predicted based on manufacturing information of the object to be treated for each processor; and
before finishing the treatment by each processor, the manufacturing lot to be treated by the processor that has been predicted to finish treatment relatively early is carried into the loader-unloader that is currently empty regardless of the order of the production plan.

2. The semiconductor manufacturing device according to claim 1, wherein when the processor starts treatment for a last or a second from the last object to be treated of the manufacturing lot that is present in the loader-unloader, the processor that finishes treatment relatively early is predicted.

3. The semiconductor manufacturing device according to claim 1, wherein the manufacturing information of the object to be treated comprises a processing time for the object to be treated and the number of objects to be treated to be included in a processing order or the manufacturing lot.

4. The semiconductor manufacturing device according to claim 1, wherein when the treatment of one manufacturing lot is finished in one processor, the treatment of another manufacturing lot is started by the one processor when another manufacturing lot to be treated by the one processor is present in any of the loader-unloaders.

5. A semiconductor manufacturing plant where a plurality of semiconductor manufacturing devices according to claim 1 are installed.

6. The semiconductor manufacturing plant according to claim 5 comprising:
an integrated controller that aggregates the manufacturing information of the processor sent from the plurality of semiconductor manufacturing devices and predicts the processor that finishes treatment relatively early;
a production management device that instructs the plurality of semiconductor manufacturing devices, based on the prediction of the integrated controller, to carry the manufacturing lot to be treated by the processor that has been predicted to finish treatment relatively early into the loader-unloader that is currently empty before finishing treatment by each processor; and
a transport device that carries the manufacturing lot into the plurality of semiconductor manufacturing devices based on the instruction from the production management device.

7. A semiconductor manufacturing method that uses a semiconductor manufacturing device provided with a plurality of processors and a number of loader-unloaders exceeding thereof, for an object to be treated that is transported according to a production plan determined as desired, carries, by the processor for treating, the object to be treated which is determined for each manufacturing lot into the loader-unloader in a unit of the manufacturing lot, thereafter transports, to the processor, and treats each object to be treated in a single unit, and then transports each object to be treated to the loader-unloader, the method comprising:
starting the treatment by each processor after the manufacturing lot of the object to be treated by each processor is carried into each loader-unloader while the remaining loader-unloader is left empty;
predicting the processor that finishes treatment relatively early, while the object to be treated is being treated by each processor, based on the manufacturing information of the object to be treated for each processor; and
carrying, before finishing treatment by each processor, the manufacturing lot to be treated by the processor that has been predicted to finish treatment relatively early into the loader-unloader that is currently empty regardless of the order of the production plan.

8. The semiconductor manufacturing method according to claim 7, wherein when the processor starts treatment for a last or a second from the last object to be treated of the manufacturing lot that is present in the loader-unloader, the processor that finishes treatment relatively early is predicted.

9. The semiconductor manufacturing method according to claim 7, wherein the manufacturing information of the object to be treated comprises a processing time for the object to be treated and the number of objects to be treated to be included in a processing order or the manufacturing lot.

10. The semiconductor manufacturing method according to claim 7, wherein when the treatment of one manufacturing lot is finished in one processor, the treatment of another manufacturing lot is started by the one processor when another manufacturing lot to be treated by the one processor is present in any of the loader-unloaders.
